(19) United States
(12) Patent Application Publication
(10) Pub. No.: US 2008/0029298 A1
(43) Pub. Date: Feb. 7, 2008

(54) Method and Structures for Implementing EMI Shielding for Rigid Cards and Flexible Circuits

(76) Inventors: Roger Allen Booth, Wappingers Falls, NY (US); Matthew Stephen Doyle, Rochester, MN (US)

Correspondence Address: IBM CORPORATION;ROCHESTER IP LAW DEPT 917, 3605 HIGHWAY 52 N, ROCHESTER, MN, 55901-7829, US

(21) Appl. No.: 11/462,875

(22) Filed: Aug. 7, 2006

(51) Int. Cl. H05K 9/00

(52) U.S. Cl. 174/350

(57) ABSTRACT

A method and structures with an EMI shielding electrically conductive coating are provided for implementing EMI shielding for rigid cards and flexible circuits. An EMI shielding electrically conductive coating is deposited on an outer layer, for example, using a vacuum sputtering deposition, chemical vapor deposition (CVD) or physical vapor deposition (PVD) process. A solder mask is applied. Mechanically cleaning removes the sputtered copper coating in areas of the outer layer that are not protected by the solder mask.

### FIELD OF THE INVENTION

The present invention relates generally to the field of electromagnetic interference (EMI) shielding, and more particularly, relates to an enhanced method and structures for implementing EMI shielding for rigid cards and flexible circuits.

### DESCRIPTION OF THE RELATED ART

The term EMI shielding should be understood to include, and to be used interchangeably with, electromagnetic compatibility (EMC), electrical conduction and/or grounding, corona shielding, radio frequency interference (RFI) shielding, and electrostatic discharge (ESD) protection.

As silicon technologies move toward smaller transistor sizes with smaller feature sizes, packaging densities increase, and operating frequencies increase, the need to contain or minimize electromagnetic interference (EMI) increases. Electromagnetic compatibility (EMC) requires shielding to contain or minimize electromagnetic interference emissions from an electronic circuit packaging design.

Cards, flexible circuits, and cables that connect processors, backplanes, storage devices, memory, and the like between servers or other systems and travel external to the central electronics complex (CEC) package or sheet metal enclosure are prime sources or avenues of likely EMI violations. Therefore, EMI solutions must be incorporated into the card, flex circuit or cable in order to maintain EMC of the overall system.

Existing solutions require additional copper ground layers introduced into the card or flex circuit or external metallic sheathing wrapped around cables and connectors. Drawbacks to these existing solutions include additional cost added to the system, which includes the cost of additional copper and dielectric layers for embedded EMI solutions or cost of the external sheathing solutions. Another disadvantage of the existing arrangements is the reduced flexibility of flexible circuits due to increased circuit thickness.

A need exists for an improved, effective mechanism for implementing EMI shielding for rigid cards and flexible circuits.

### SUMMARY OF THE INVENTION

A principal aspect of the present invention is to provide an enhanced method for implementing EMI shielding and structures with an EMI shielding electrically conductive coating for rigid cards and flexible circuits. Other important aspects of the present invention are to provide such an enhanced method for implementing EMI shielding and structures with an EMI shielding electrically conductive coating for rigid cards and flexible circuits substantially without negative effect and that overcome many of the disadvantages of prior art arrangements.

In brief, a method and structures with an EMI shielding electrically conductive coating are provided for implementing EMI shielding for rigid cards and flexible circuits. An EMI shielding electrically conductive coating is deposited on an outer layer, for example, using a vacuum sputtering deposition, chemical vapor deposition (CVD) or physical vapor deposition (PVD) process. A solder mask is applied. Mechanically cleaning removes the sputtered copper coating in areas of the outer layer that are not protected by the solder mask.

In accordance with features of the invention, the electrically conductive coating is formed, for example, of a thin copper coating. The thin copper coating has a thickness in a range between 1 to 10 microns (1 to 10 μm). The thin copper coating eliminates the need for a conventional external EMC copper layer having a thickness of about 1.4 mils or 1.4 10⁻³ inches typically provided on a TOP layer of the rigid or flexible circuit structure. A preferred electrically conductive material is copper, while various other electrically conductive materials can be used, for example, a selected metal or metal alloy, such as, nickel, gold, and alloys of these metals, or a selected combination of a metal and metal alloy.

### BRIEF DESCRIPTION OF THE DRAWINGS

The present invention together with the above and other objects and advantages may best be understood from the following detailed description of the preferred embodiments of the invention illustrated in the drawings, wherein:

FIGS. 1-5 are side views not to scale illustrating exemplary fabrication sequence steps for fabricating an exemplary structure with an EMI shielding electrically conductive sputtered coating in accordance with a first preferred embodiment; and

FIGS. 6-10 are side views not to scale illustrating other exemplary fabrication sequence steps for fabricating another exemplary structure with an EMI shielding electrically conductive sputtered coating in accordance with another preferred embodiment.

### DETAILED DESCRIPTION OF THE PREFERRED EMBODIMENTS

In accordance with features of the invention, a method and structure with copper sputtering EMI shielding are provided allows for the elimination of conventional EMC shielding layers typically required for flexible circuits in order to meet EMC requirements. The invention includes two embodiments, which allow for different applications of the same electrically conductive sputtered coating using a sputtering process, which maintains EMC without requiring additional circuit layers and associated cost.

In brief summary, in accordance with features of the invention, a circuit is processed as normal, up to the point where the TOP or PADCAP layer is normally about to be covered with solder mask. With a PADCAP layer the outer surfaces of the board have pads but no tracks, and signal layers are only created on the inner planes, and tracks are connected to the surface pads by vias. Next depending upon which embodiment of this invention is utilized, copper Cu or other electrically conductive material is deposited, such as sputter coated, to either the PADCAP dielectric material or a large-pitch copper mesh patterned to the PADCAP.

Existing vacuum sputtering deposition, chemical vapor deposition (CVD) or physical vapor deposition (PVD) processes are used to deposit the electrically conductive coating. A preferred electrically conductive material is copper, while it should be understood that the present invention is not limited to a thin copper coating, various other electrically conductive materials can be used, for example, a selected metal or metal alloy, such as, nickel, gold, and alloys of these metals.

In accordance with features of the invention, the Cu sputtered coating or other electrically conductive material sputtered coating forms an EMC boundary. Then a solder mask then is applied as normal. The EMC copper sputter coating is now embedded into the circuit. Prior to attaching connectors and the like, the pads are mechanically cleaned which removes the sputtered copper coating in those areas. The solder mask protects the sputtered copper coating in the other areas.

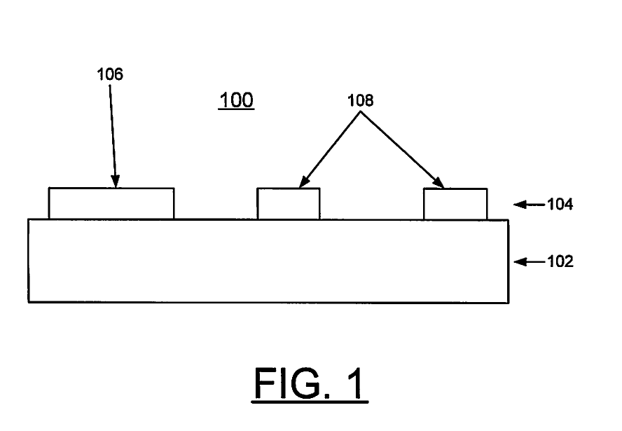

In accordance with features of the invention, a set of predefined simple wiring rules are required on the TOP layer to isolate EMI shield from the rest of the wiring and to contact the EMI shield to the chassis ground. These rules are not outside the scope of typical wiring rules, and substantially no complexity or cost is added by the implementations of EMC copper sputter coatings of the invention. The Cu sputtering coating eliminates the need for a conventional external EMC copper layer having a thickness of about 1.4 mils or 1.4 10⁻³ inches typically provided on a TOP layer of the rigid or flexible circuit structure. Having reference now to the drawings, in FIG. 1, there is shown an exemplary first processing step with an exemplary initial circuit structure generally designated by the reference character 100 provided from a normal fabrication process. As shown, a core layer 102, such as a conventional flexible circuit or printed circuit board (PCB) core dielectric layer, carries a TOP layer 104 or outer most copper layer. The TOP layer 104 includes a pad 106 for connection to a connector (not shown) and a ground (GND) mesh 108.

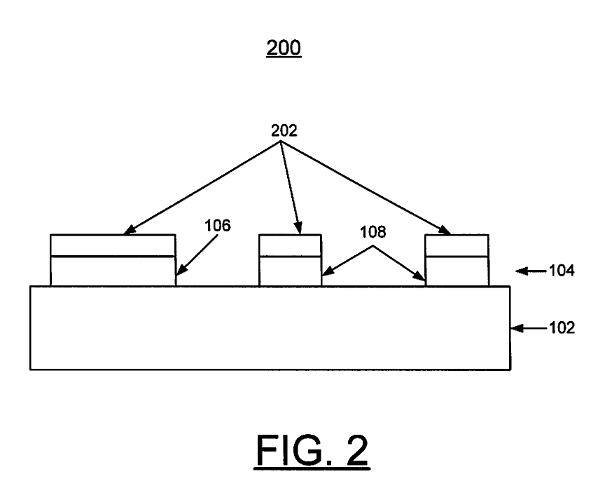

FIG. 2 illustrates a next conventional plating processing step generally designated by the reference character 200 where a plating material 202, such as copper is added to increase the thickness of the connector pad 106 and the ground (GND) mesh 108.

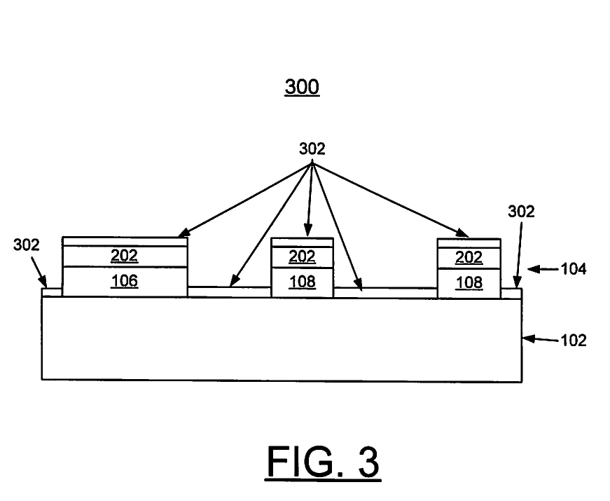

Referring now to FIG. 3, there is shown a next deposition processing step generally designated by the reference character 300 in accordance with a first preferred embodiment where an electrically conductive coating 302 is added to the TOP surface 104, the plated pad 106 and the plated ground (GND) mesh 108, for example, using a known vapor sputter deposition system in a vacuum.

In accordance with features of the invention, the electrically conductive coating 302 forms an EMC boundary for the circuit structure 100. Conventional vacuum sputtering deposition, chemical vapor deposition (CVD) or physical vapor deposition (PVD) processes are used to provide a generally thin electrically conductive coating 302.

For example, the electrically conductive coating 302 is a thin coating having a thickness typically in a range from about 100 angstroms to less than 10 microns. For example, with a copper sputtered coating 302, the thin copper sputtered coating thickness is typically in a range from 1 to 10 microns (1 to 10 μm).

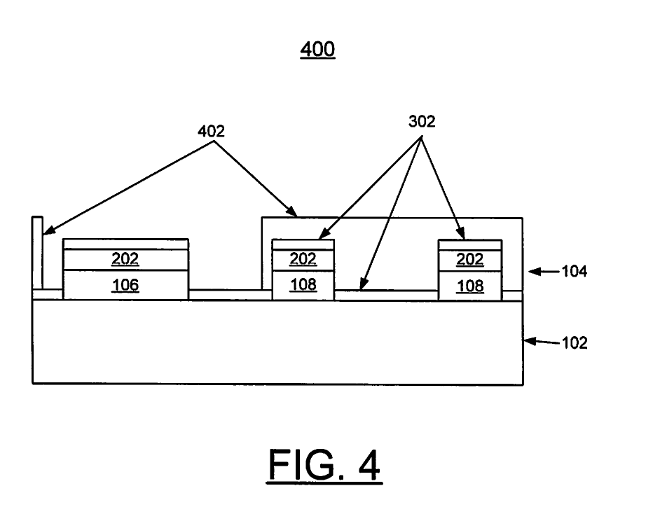

FIG. 4 illustrates a next conventional solder mask processing step generally designated by the reference character 400 where a solder mask 402 is applied spaced from the connector pad 106 and above the ground (GND) mesh 108.

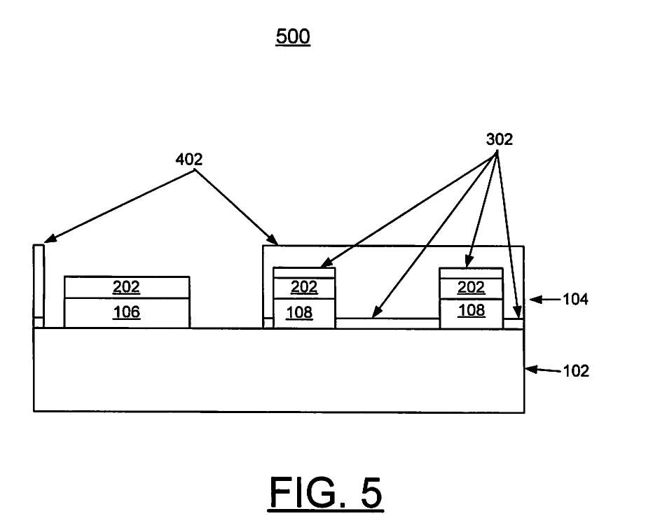

FIG. 5 illustrates a final conventional mechanical cleaning processing step generally designated by the reference character 500 before connectors and the like. In the mechanical cleaning step 500, the electrically conductive sputtered coating 302 is removed in the area not covered by the solder mask 402. The electrically conductive sputtered coating 302 is removed from the area of the connector pad 106. The electrically conductive sputtered coating 302 is retained in the area of the ground (GND) mesh 108 where protected by the solder mask 402.

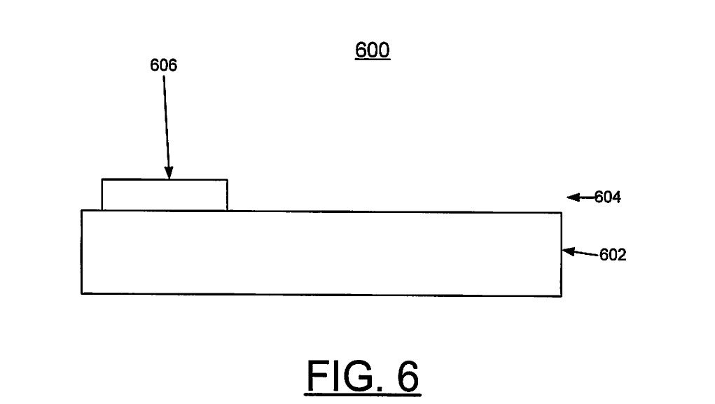

Referring now to FIGS. 6-10, there are shown other exemplary fabrication sequence steps for fabricating another exemplary structure with an EMI shielding electrically conductive sputtered coating in accordance with another preferred embodiment.

In FIG. 6, there is shown an exemplary first processing step with an exemplary initial circuit structure generally designated by the reference character 600 provided from a normal fabrication process. As shown, a core layer 602, such as a conventional PCB core dielectric layer, carries a TOP layer 604 or outer most copper layer. The TOP layer 104 includes a pad 106 for connection to a connector (not shown).

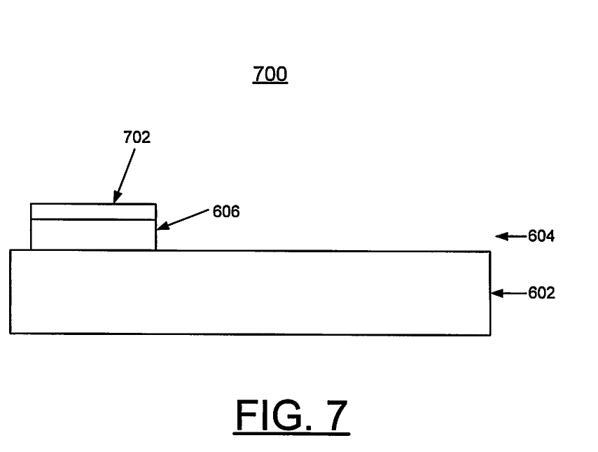

FIG. 7 illustrates a next conventional plating processing step generally designated by the reference character 700 where a plating material 702, such as copper is added to increase the thickness of the connector pad 606.

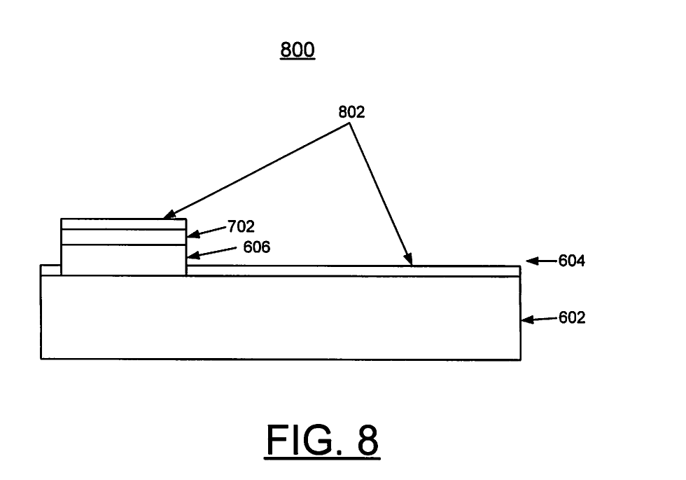

Referring now to FIG. 8, there is shown a next vacuum sputtering deposition processing step generally designated by the reference character 800 in accordance with a preferred embodiment where an electrically conductive sputtered coating 802 is added to the TOP surface 104, and the plated pad 106, for example, using a known vapor sputter deposition system in a vacuum. The generally thin electrically conductive sputtered coating 802 forms an EMC boundary for the circuit structure 600.

For example, the electrically conductive sputtered coating 802 is generally the same as electrically conductive sputtered coating 302, a thin coating having a thickness typically in a range from about 100 angstroms to less than 10 microns. For example, with a copper sputtered coating 802, the thin copper sputtered coating thickness is typically in a range from 1 to 10 microns (1 to 10 μm).

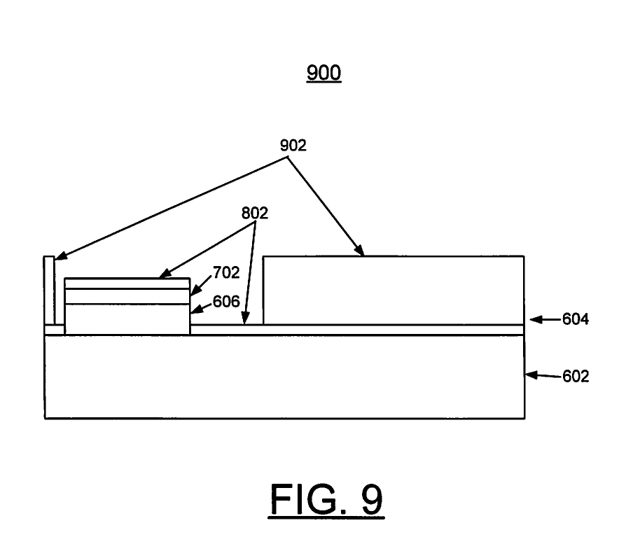

FIG. 9 illustrates a next conventional solder mask processing step generally designated by the reference character 900 where a solder mask 902 is applied spaced from the connector pad 106.

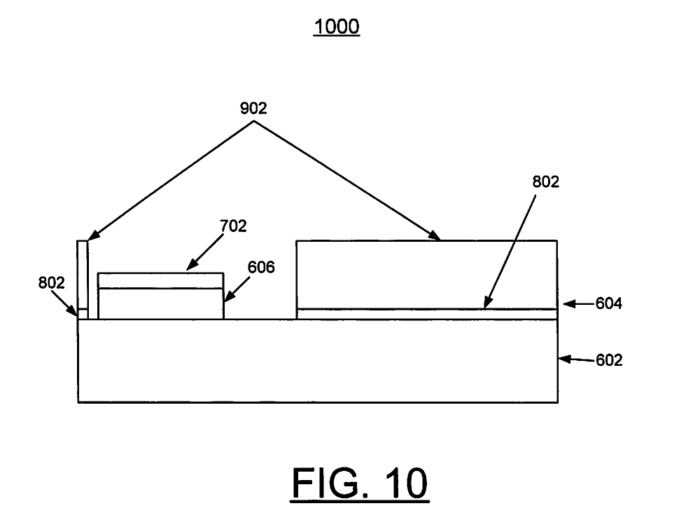

FIG. 10 illustrates a final conventional mechanical cleaning processing step generally designated by the reference character 1000 before attaching connectors and the like (not shown). In the mechanical cleaning step 1000, the electrically conductive sputtered coating 802 is removed in the area not covered by the solder mask 902. The electrically conductive sputtered coating 802 is removed from the area of the connector pad 606. The electrically conductive sputtered coating 802 is retained in the area protected by the solder mask 902.

While the present invention has been described with reference to the details of the embodiments of the invention shown in the drawing, these details are not intended to limit the scope of the invention as claimed in the appended claims.

What is claimed is:

1. A method for implementing EMI shielding for rigid cards and flexible circuits comprising the steps of:
depositing an EMI shielding electrically conductive coating on an outer circuit layer using a selected deposition process;
applying a solder mask over at least a portion of said EMI shielding electrically conductive coating; and
removing said EMI shielding electrically conductive coating in selected areas of the outer circuit layer that are not protected by said solder mask.

2. A method for implementing EMI shielding for rigid cards and flexible circuits as recited in claim 1 wherein said selected deposition process includes one of a vacuum sputtering deposition process, a chemical vapor deposition (CVD) process, or physical vapor deposition (PVD) process.

3. A method for implementing EMI shielding for rigid cards and flexible circuits as recited in claim 1 wherein the step of removing said EMI shielding electrically conductive coating in selected areas includes mechanically cleaning.

4. A method for implementing EMI shielding for rigid cards and flexible circuits as recited in claim 1 wherein the step of removing said EMI shielding electrically conductive coating in selected areas of the outer circuit layer that are not protected by said solder mask includes removing said EMI shielding electrically conductive coating in selected areas of connector pads.

5. A method for implementing EMI shielding for rigid cards and flexible circuits as recited in claim 1 wherein said EMI shielding electrically conductive coating is formed of a thin copper coating, said thin copper coating having a thickness of less than 10 microns.

6. A method for implementing EMI shielding for rigid cards and flexible circuits as recited in claim 1 wherein said EMI shielding electrically conductive coating includes a copper coating having a thickness in a range between 1 to 10 microns (1 to 10 μm).

7. A method for implementing EMI shielding for rigid cards and flexible circuits as recited in claim 1 wherein said EMI shielding electrically conductive coating is formed of a selected one of a metal or a metal alloy.

8. A method for implementing EMI shielding for rigid cards and flexible circuits as recited in claim 1 wherein said EMI shielding electrically conductive coating is formed of a selected combination of a metal and a metal alloy.

9. A method for implementing EMI shielding for rigid cards and flexible circuits as recited in claim 1 wherein the step of depositing an EMI shielding electrically conductive coating on an outer circuit layer includes depositing an EMI shielding electrically conductive coating on a dielectric material.

10. A method for implementing EMI shielding for rigid cards and flexible circuits as recited in claim 1 wherein the step of depositing an EMI shielding electrically conductive coating on an outer circuit layer includes depositing an EMI shielding electrically conductive coating on a ground mesh.

11. A structure for implementing EMI shielding for rigid cards and flexible circuits comprising:
an outer circuit layer;
an EMI shielding electrically conductive coating disposed on said outer circuit layer; and
a solder mask over at least a portion of said EMI shielding electrically conductive coating for protecting said EMI shielding electrically conductive coating in selected areas of the outer circuit layer.

12. A structure for implementing EMI shielding for rigid cards and flexible circuits as recited in claim 11 wherein said outer circuit layer includes a connector pad, and wherein said EMI shielding electrically conductive coating is removed from an area of said connector pad.

13. A structure for implementing EMI shielding for rigid cards and flexible circuits as recited in claim 11 wherein said outer circuit layer includes a dielectric material, and wherein said EMI shielding electrically conductive coating is disposed on said dielectric material.

14. A structure for implementing EMI shielding for rigid cards and flexible circuits as recited in claim 11 wherein said outer circuit layer includes a ground mesh, and wherein said EMI shielding electrically conductive coating is disposed on said ground mesh.

15. A structure for implementing EMI shielding for rigid cards and flexible circuits as recited in claim 11 wherein said EMI shielding electrically conductive coating is formed of a selected one of a metal or a metal alloy.

16. A structure for implementing EMI shielding for rigid cards and flexible circuits as recited in claim 11 wherein said wherein said EMI shielding electrically conductive coating is formed of a selected combination of a metal and a metal alloy.

17. A structure for implementing EMI shielding for rigid cards and flexible circuits as recited in claim 11 wherein said wherein said EMI shielding electrically conductive coating is formed of copper.

18. A structure for implementing EMI shielding for rigid cards and flexible circuits as recited in claim 11 wherein said EMI shielding electrically conductive coating includes a copper coating having a thickness in a range between 1 to 10 microns (1 to 10 μm).

19. A structure for implementing EMI shielding for rigid cards and flexible circuits as recited in claim 11 wherein said EMI shielding electrically conductive coating includes a metal coating having a thickness in a range between 100 angstroms and 10 microns.

20. A structure for implementing EMI shielding for rigid cards and flexible circuits as recited in claim 11 wherein said EMI shielding electrically conductive coating is removed in selected areas of connector pads that are not protected by said solder mask.
